(19) United States
(12) Patent Application Publication
(10) Pub. No.: US 2007/0052074 A1
(43) Pub. Date: Mar. 8, 2007

(54) Optical coupling element, method for producing the optical coupling element, and electronic device equipped with the optical coupling element

(75) Inventor: Yasushi Hasegawa, Nara (JP)

Correspondence Address: BIRCH STEWART KOLASCH & BIRCH, PO BOX 747, FALLS CHURCH, VA, 22040-0747, US

(73) Assignee: Sharp Kabushiki Kaisha

(21) Appl. No.: 11/510,598

(22) Filed: Aug. 28, 2006

(30) Foreign Application Priority Data
Sep. 8, 2005 (JP) 2005-260853

(51) Int. Cl. H01L 23/495

(52) U.S. Cl. 257/676

(57) ABSTRACT

After a light emitting element is mounted to a header of a light emitting lead frame, a light receiving element is mounted to a header of a light receiving lead frame and a power element is mounted to a header of a power lead frame, the light emitting element, the light receiving element and the power element are connected to respective lead portions with wires, and in a state with the light emitting element, and the light receiving element and the power element, disposed facing each other, they are entirely coated with a primary molding resin, and the primary molding resin and a heat sink formed in a heat dissipating lead frame are coated with a secondary molding resin. Also, a structure is adopted in which the lead terminal of the power element and the heat dissipating lead frame are stacked together, and joined at this stacked portion.

### BACKGROUND OF THE INVENTION

This application claims priority under 35 U.S.C. § 119(a) on Japanese Patent Application No. 2005-260853 filed in Japan on Sep. 8, 2005, the entire contents of which are hereby incorporated by reference.

The present invention relates to optical coupling elements that perform signal transmission by insulating between input and output, methods for producing optical coupling elements, and electronic devices equipped with an optical coupling element.

A conventional structure of an optical coupling element equipped with a power element is shown in FIGS. 8 and 9.

In this optical coupling element, after a light emitting element 101 is mounted to a header 111a of a light emitting lead frame 111, a light receiving element 102 is mounted to a header 121a of a light receiving lead frame 121, and a power element 103 is mounted to a header 131a of a power lead frame 131, a connection is made to each lead portion with wires 141, and pre-coating or the like is performed if necessary. The optical coupling element has a structure in which, in a state with the light emitting element 101 mounted to the header 111a of the light emitting lead frame 111, and the light receiving element 102 mounted to the header 121a of the light receiving lead frame 121 and the power element 103 mounted to the header 131a of the power lead frame 131, disposed facing each other, the light emitting element 101, the light receiving element 102 and the power element 103 are entirely coated with a primary molding resin 151, and further, the entire primary molding resin 151 is coated with a secondary molding resin 161.

The power element 103 is for output, and is controlled by the light receiving element 102, so it is disposed on the side of the light receiving element 102. The area of a header 130a, which is a mounting portion of the power element 103, is as large as possible in order to dissipate heat it generates itself. Because a component with greater power consumption also generates more heat, the size of the package is increased (also increasing the number of lead pins), thus increasing the heat dissipating effect.

Also, with respect to improving the heat dissipation of a small package, technology has been proposed such as in which heat dissipation is improved using a portion of a lead frame (for example, see JP H4-76062U), and in which a suspension lead is added to a header to which the power element is mounted, and after resin molding, a heat sink is spot welded to this suspension lead (for example, see JP 2003-86740A).

In present electronic devices, reductions in the size and increases in the functionality of devices is now progressing, and reductions in the size of substrates on which optical coupling elements are mounted is also progressing. When a reduction in the size of substrates on which optical coupling elements are mounted progresses, naturally a reduction in the size of the elements is also sought. However, in the type of optical coupling element that has a power element, it is necessary to have a heat dissipation structure commensurate with the amount of power consumption, and in order to reduce the size of a package for which some degree of size is necessary, an optical coupling element is necessary in which an increase in heat resistance is suppressed, and in which a power element is mounted that has a heat dissipation structure with good productivity.

In this case, as in the optical coupling device disclosed in above JP H4-76062U, there is the problem that with a structure in which a small portion of a frame is used instead of a heat sink, there is a limit to the size of the heat sink, and because the heat dissipation effect is small, this heat sink cannot be used in an optical coupling element having at least a certain amount of power consumption.

Also, as in the semiconductor device disclosed in above JP 2003-86740A, with respect to a structure in which a heat sink is spot welded to a suspension pin that has been led out from a package, there is the problem that because a plurality of differing electrical potentials are present in an optical coupling element in which a plurality of chips for a power element and light receiving element are mounted, due to the frame construction it is actually difficult to lead out the suspension pin that needs to be spot welded from both sides of the package.

### SUMMARY OF THE INVENTION

The present invention was made in order to address these problems, and it is an object thereof to provide an optical coupling element that has excellent heat dissipation with a comparatively simple structure, a method for producing the optical coupling element, and an electronic device equipped with the optical coupling element.

In order to address the above problems, in the optical coupling element of the present invention, in a state in which a light emitting element that has been mounted to a light emitting lead frame, and a light receiving element that has been mounted to a light receiving lead frame and a power element that has been mounted to a power lead frame, have been disposed facing each other, the light emitting element, the light receiving element and the power element are entirely coated with a primary molding resin, and the primary molding resin and a heat sink formed in a heat dissipating lead frame are coated with a secondary molding resin, and inside the secondary molding resin, a lead terminal of the power element and the heat dissipating lead frame are in contact.

A connection is made in the portion where the lead terminal and the heat dissipating lead frame make contact. Specifically, any of the connection methods of making a connection by high melting point soldering, making a connection by spot welding, or making a connection with an adhesive or adhesive sheet with good heat dissipation (fixing) is adopted. Also, the heat dissipating lead frame may be provided with a bent portion for fixing in space such that it is exposed from the secondary molding resin. Also, in the present invention, a lead terminal of the heat dissipating lead frame that has been led outside is used as the lead terminal of the power element.

A method for producing an optical coupling element with the above configuration includes a step of, in a state in which a light emitting element that has been mounted to a light emitting lead frame, and a light receiving element that has been mounted to a light receiving lead frame and a power element that has been mounted to a power lead frame, have been disposed facing each other, entirely molding the light emitting element, the light receiving element and the power element with a primary molding resin, a step of forming a lead terminal by cutting the power lead frame to which the power element, which is led out from the first molding resin, has been mounted, and a step of stacking together the lead terminal and the heat dissipating lead frame in which a heat sink is formed, and in this state, molding the primary molding resin and the heat sink entirely with a secondary molding resin.

That is, the optical coupling element of the present invention is a two-layer transfer mold-type optical coupling element, and after executing a primary molding resin, a heat sink is fixed to a lead terminal to which a power element is mounted, and then secondary molding is executed. Fixing of the heat sink is performed using, for example, spot welding, soldering with a high melting point, or an adhesive or adhesive sheet with good heat dissipation. Also, because a frame-like heat sink that is also used as a lead pin is used, there is the advantage that the production processes can be performed in series.

According to the optical coupling element and the method for producing the optical coupling element of the present invention, along with being possible to improve the heat dissipation properties of the optical coupling element, by providing the connecting portion that connects with the heat sink in the secondary molding resin, it is possible to increase the fixing strength of the heat sink. Also, by using a heat sink that is used also as a lead also as a frame, it is possible to carry out production with a series of processes, and therefore it is possible to provide an inexpensive product with effective heat dissipation.

### BRIEF DESCRIPTION OF THE DRAWINGS

FIG. 1 is a cross-sectional diagram that shows the structure of an optical coupling element according to Embodiment 1 of the present invention.

FIG. 2 is a plan view that shows a light receiving element and power element that have been mounted to a frame substrate before processing of a light receiving lead frame and power lead frame.

FIG. 3 is a plan view that shows a state in which a light emitting element, light receiving element and power element are entirely molded with a primary molding resin.

FIG. 4 is a plan view that shows a state in which a lead terminal is formed by cutting a power lead frame at a portion that is inside a secondary molding resin after the primary mold.

FIG. 5 is a plan view that shows the structure of a heat sink.

FIG. 6 is a plan view that shows a state in which both frame substrates are stacked together, and a lead terminal and a bent portion of a heat dissipating lead frame are aligned.

FIG. 7 is a cross-sectional diagram that shows the structure of an optical coupling element according to Embodiment 2 of the present invention.

FIG. 8 is a cross-sectional diagram that shows the structure of a conventional optical coupling element.

FIG. 9 is a plan view that shows a light receiving element and power element that have been mounted to a frame substrate before processing of a light receiving lead frame and power lead frame.

### DESCRIPTION OF THE PREFERRED EMBODIMENTS

Hereinafter, embodiments of the present invention will be described with reference to the accompanying drawings.

<Embodiment 1>

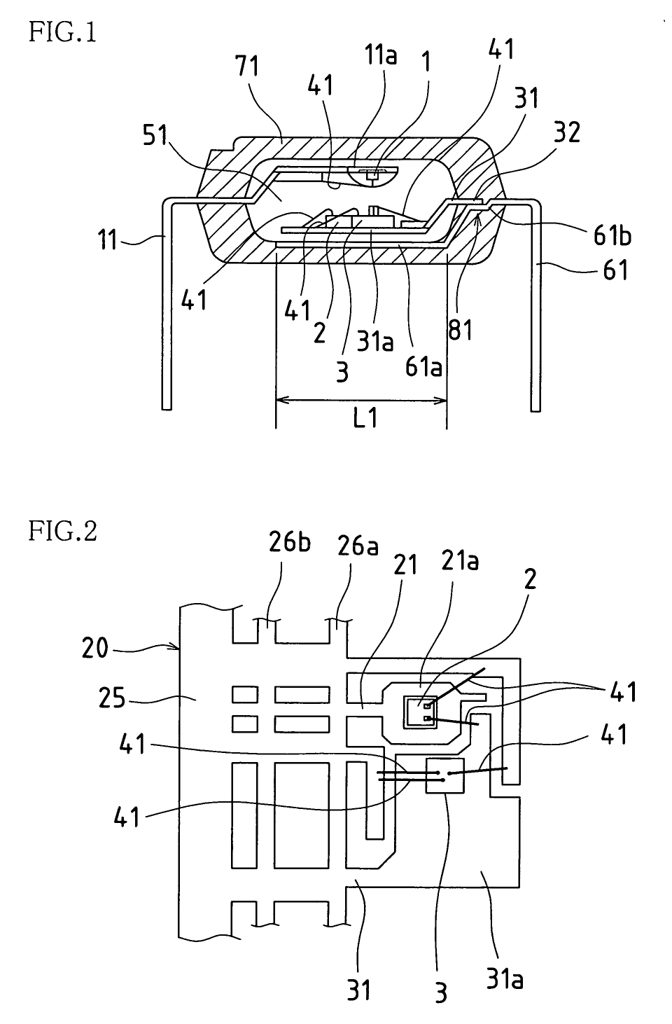

FIG. 1 is a cross-sectional diagram that shows the structure of an optical coupling element according to Embodiment 1 of the present invention, and FIG. 2 is a plan view that shows a light receiving element and power element that have been mounted to a frame substrate before processing of a light receiving lead frame and power lead frame.

In the optical coupling element of Embodiment 1, after a light emitting element 1 is mounted to a header 11a of a light emitting lead frame 11, a light receiving element 2 is mounted to a header 21a (however, not shown in FIG. 1, because here a cross-section is taken of a heat dissipating lead frame 61 portion, described later) of a light receiving lead frame 21, and a power element 3 is mounted to a header 31a of a power lead frame 31, the light emitting element 1, the light receiving element 2 and the power element 3 are connected to each lead portion with wires 41, and pre-coating or the like is performed if necessary. In a state with the light emitting element 1 mounted to the header 11a of the light emitting lead frame 11, and the light receiving element 2 mounted to the header 21a of the light receiving lead frame 21 and the power element 3 mounted to the header 31a of the power lead frame 31, disposed facing each other, the light emitting element 1, the light receiving element 2 and the power element 3 are entirely coated with a primary molding resin 51, and the primary molding resin 51 and a heat sink 61a that is formed in the heat dissipating lead frame 61 are coated with a secondary molding resin 71. Also, the optical coupling element has a structure in which a lead terminal 32 of the power element 3 and the heat dissipating lead frame 61 are stacked together within the secondary molding resin 71, and joined at a stacked portion 81 where they are stacked together.

In the heat dissipating lead frame 61, a bent portion (step portion) 61b is formed in the stacked portion 81. By disposing the end portion of the lead terminal 32 of the power element 3 in the bent portion 61b such that the end portion is allowed to meet with the bent portion 61b, it is possible to align the position of the heat sink 61a relative to the primary molding resin 51. Also, in Embodiment 1, the heat sink 61a, in a state in which it is provided attached to the surface (the bottom face in FIG. 1) of the primary molding resin 51, is in a state embedded in the secondary molding resin 71.

Next is a description of a method for producing an optical coupling element with the above configuration.

A frame substrate 20 before processing of a light receiving lead frame and a power lead frame, as shown with a portion thereof enlarged in FIG. 2, is configured with a cradle 25, lead frame portions (such as the light receiving lead frame 21 and the power lead frame 31) connected to the cradle 25, and a primary tie bar portion 26a and secondary tie bar portion 26b that link these lead frames. Also, although not shown, a frame substrate before processing of a light emitting lead frame also has a similar configuration.

In this sort of frame substrate 20, the light receiving element 2 is die-bonded to the header 21a of the light receiving lead frame 21, the power element 3 is die-bonded to the header 31a of the power lead frame 31, and afterward, a connection is made to each lead portion with wire bonding. Likewise, the light emitting element 1 is die-bonded to the header 11a of the light emitting lead frame 11, and afterward, it is connected to a lead portion with wire bonding.

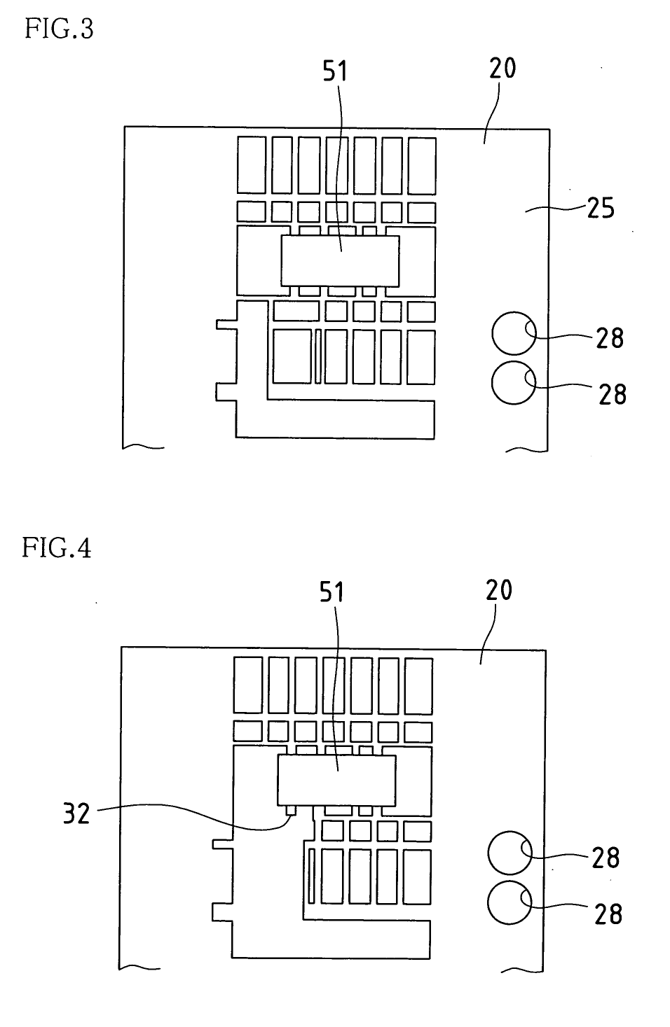

Next, both frame substrates are disposed facing each other such that the light emitting element 1 and the light receiving element 2 have approximately the same optical axis, and in this state, the light emitting element 1, the light receiving element 2 and the power element 3 are entirely molded with the primary molding resin 51. FIG. 3 is a plan view that shows this state. That is, it shows a state in which the frame substrate 20 on the light receiving element 2 side and a frame substrate on the light emitting element 1 side (the bottom side in FIG. 3) have been stacked together vertically.

Then, after the primary mold is finished, the tie bar portions 26a and 26b and thickness burrs of the primary molding resin 51, which is translucent resin, are removed, but when removing these tie bar portions 26a and 26b and the thickness burrs, the lead terminal 32 is formed by cutting, at the portion that will be inside the secondary molding resin 71, the lead terminal portion that connects to the header 31a to which the power element 3 is mounted, leaving the portion to which the heat sink 61a is afterward mounted. FIG. 4 is a plan view that shows this state.

Afterward, the heat sink 61a is attached to the bottom face of the primary molding resin 51, and the heat dissipating lead frame 61 having the bent portion 61b bent such that it is stacked with the cut lead terminal 32 is laid on, and the stacked portion 81 where they are stacked together is fixed.

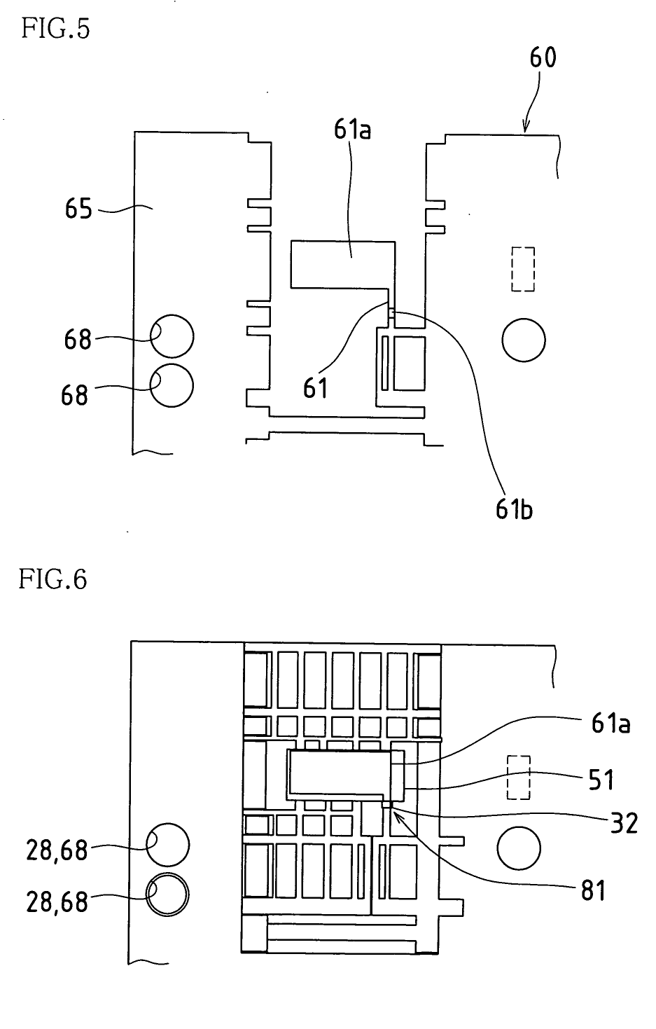

FIG. 5 shows the structure of the heat sink 61a. The heat sink 61a is a frame structure having the heat dissipation lead frame 61 in which the bent portion 61b described above is formed, and the overall shape of the frame substrate 60 is the same as the shape of the frame substrate 20 shown in FIG. 2. Also, in the frame substrate 60, two opening portions 68 for aligning are provided in the cradle portion 65, and these opening portions 68 are formed such that they correspond with two opening portions 28 for aligning that are formed in the cradle portion 25 of the frame substrate 20 of the light receiving element 2 side shown in FIG. 3.

Accordingly, the above alignment of the heat sink 61a and the primary molding resin 51, and the alignment of the cut lead terminal 32 and the bent portion 61b of the heat dissipating lead frame 61, can be performed by matching the opening portions 28 and 68 formed in the cradle portion with each other.

FIG. 6 shows a state in which both frame substrates are stacked together in this manner, and the lead terminal 32 and the bent portion 61b of the heat dissipating lead frame 61 have been aligned. However, FIG. 6 shows a state in which they are stacked with the frame substrate 60 of the heat sink 61a below, and above the frame substrate 20 shown in FIG. 4 (however, the frame substrate of the light emitting lead frame 11 also in the same body) with front and back reversed.

With respect to the method of fixing the stacked portion 81 at this time, the stacked portion 81 is fixed using spot welding in order to insure conductivity with the cut lead terminal 32. However, another method may be used for this fixing if it has a fixing strength that can withstand molding of the secondary mold, and insures conductivity, so other than spot welding, soldering may also be used. In this case, it is preferable to use soldering with a high melting point, such that it can withstand high temperatures when molding the secondary mold. Other than spot welding or soldering, the stacked portion 81 may be glued using an adhesive or adhesive sheet that has heat resistance and conductivity.

After fixing the stacked portion 81 in this manner, the primary molding resin 51 including the stacked portion 81 and the heat sink 61a are entirely molded with the optically shielding secondary molding resin 71, and forming and the like is performed, producing the optical coupling element shown in FIG. 1.

Thus, the lead that is led out from the secondary molding resin 71 and used as the portion where the power element 3 is mounted, becomes the heat dissipating lead frame 61 fixed to the lead terminal 32 after formation of the primary molding resin 51. That is, the lead connected to the header 61a to which the power element 3 is mounted, in the secondary molding resin 71, is divided into the heat dissipating lead frame 61 that is led outside, and the heat sink 61a attached to the bottom face of the primary molding resin 51.

Accordingly, the heat that is generated with the power consumed by the power element 3 is dissipated from both the heat dissipating lead frame 61 and the heat sink 61a, and heat resistance decreases, so heat tolerance increases.

<Embodiment 2>

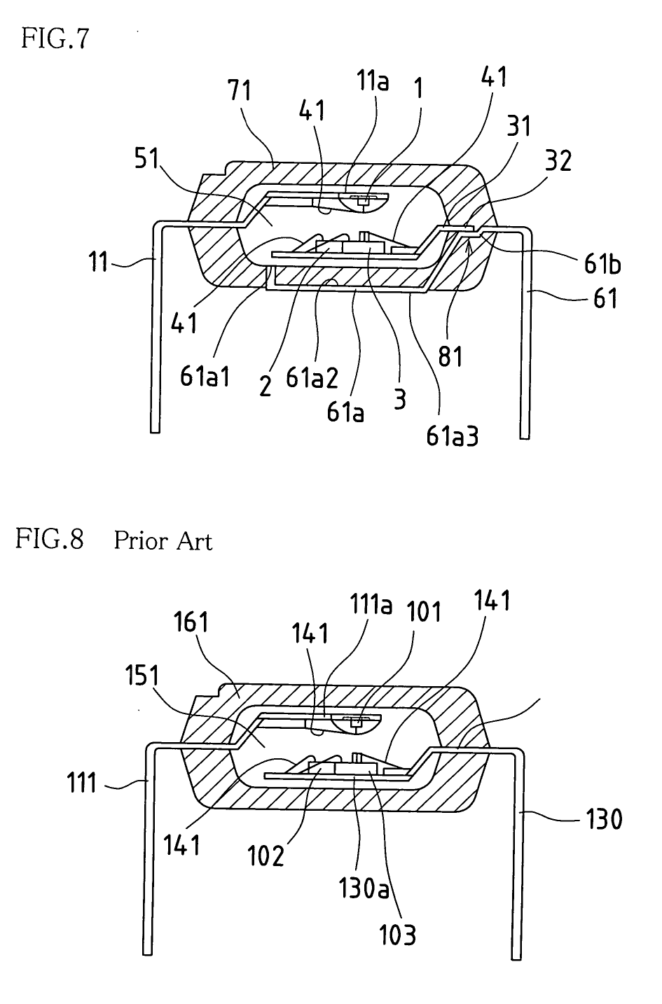

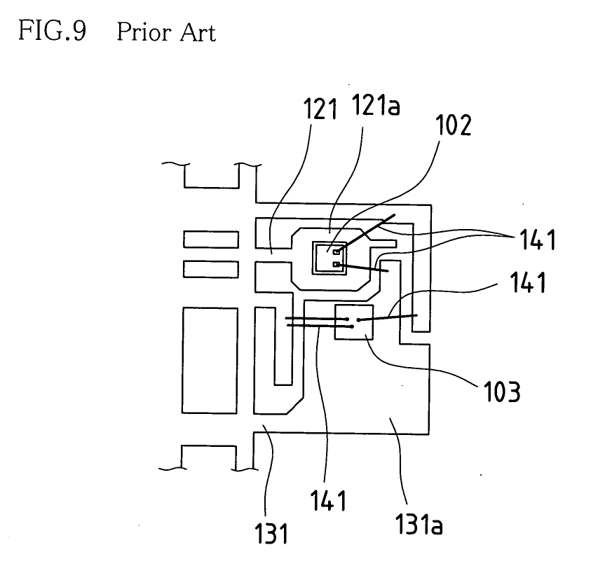

FIG. 7 is a cross-sectional diagram that shows the structure of an optical coupling element according to Embodiment 2 of the present invention.

In above Embodiment 1, the heat sink 61a is in a state completely embedded within the secondary molding resin 71, but in order to allow the function as the heat sink 61 to be maximally exhibited, it is preferable that a portion of the heat sink 61a is exposed outside of the secondary molding resin 71. In consideration of this point, in Embodiment 2 the shape of the heat sink 61a is devised as shown in FIG. 7.

That is, by forming an end portion of the heat sink 61a bent upward, and allowing that bent end portion 61a1 to make contact with the bottom face of the primary molding resin 51, a shape is adopted in which a space is formed where the secondary molding resin is filled up between the bottom face of the primary resin mold 51 and an upper face 61a2 of the heat sink 61a, and a bottom face 61a3 of the heat sink 61 makes contact with an interior face of a secondary molding die that is not shown. Thus, when the secondary molding is performed, the bottom face 61a3 of the heat sink 61 is reliably exposed outside, and the heat dissipation effect is further obtained.

Because the optical coupling element in above Embodiment 1 has a structure in which the heat sink 61a is embedded within the secondary molding resin 71, the heat generated by the power element 3 is mainly covered by the heat dissipating lead frame 61, which has a large heat capacity, and so it is effective for a type of optical coupling element that has a comparatively small amount of power (about 0.2 to 1A).

Also, because the optical coupling element is an insulating element, and the heat sink 61a has the same electric potential as the power element 3 on the secondary side, there is the problem that the insulating distance between the primary and secondary sides becomes small due to the heat sink 61a lying in between. In order to avoid this problem, it is preferable that a length L1 (see FIG. 1) in the direction of the primary side of the heat sink 61a is generally about 2.0 to 3.4 mm, although it will differ depending on the package size and set specifications that are used.

Also, in the manner of a solid state relay, with respect to an element that takes several hundred V of voltage between terminals on the secondary side, at least a certain amount of distance is necessary between those terminals, so it is preferable that the distance between the heat sink 61a and another terminal is generally about 1 to 3 mm.

According to the present invention, a structure is adopted in which the heat sink has a frame-like shape in which the heat sink is also used as a lead terminal, and frames are stacked together after a primary mold, so it is possible to automate the production process, and without an extreme fall in production takt, it is possible to stably and inexpensively provide an optical coupling element with good heat dissipation properties.

The optical coupling element of the present invention is suitably used in various electronic devices provided with a circuit that performs signal transmission by insulating between input and output, such as DVDs, TVs, VTRS, STBs, CDs, MDs, power supply devices, home appliances, and inverter control devices.

The present invention may be embodied in various other forms without departing from the gist or essential characteristics thereof The embodiments disclosed in this application are to be considered in all respects as illustrative and not limiting. The scope of the invention is indicated by the appended claims rather than by the foregoing description, and all modifications or changes that come within the meaning and range of equivalency of the claims are intended to be embraced therein.

1. An optical coupling element wherein, in a state in which a light emitting element that has been mounted to a light emitting lead frame, and a light receiving element that has been mounted to a light receiving lead frame and a power element that has been mounted to a power lead frame, have been disposed facing each other, the light emitting element, the light receiving element and the power element are entirely coated with a primary molding resin, and the primary molding resin and a heat sink formed in a heat dissipating lead frame are coated with a secondary molding resin, and inside the secondary molding resin, a lead terminal of the power element and the heat dissipating lead frame are in contact.

2. The optical coupling element according to claim 1, wherein a connection is made in the portion where the lead terminal and the heat dissipating lead frame make contact.

3. The optical coupling element according to claim 1, wherein a connection is made in the portion where the lead terminal and the heat dissipating lead frame make contact by soldering.

4. The optical coupling element according to claim 1, wherein a connection is made in the portion where the lead terminal and the heat dissipating lead frame make contact by welding.

5. The optical coupling element according to claim 1, wherein a connection is made in the portion where the lead terminal and the heat dissipating lead frame make contact by gluing.

6. The optical coupling element according to claim 1, wherein the heat dissipating lead frame is provided with a bent portion for aligning with the lead terminal.

7. The optical coupling element according to claim 2, wherein the heat dissipating lead frame is provided with a bent portion for aligning with the lead terminal.

8. The optical coupling element according to claim 3, wherein the heat dissipating lead frame is provided with a bent portion for aligning with the lead terminal.

9. The optical coupling element according to claim 4, wherein the heat dissipating lead frame is provided with a bent portion for aligning with the lead terminal.

10. The optical coupling element according to claim 5, wherein the heat dissipating lead frame is provided with a bent portion for aligning with the lead terminal.

11. The optical coupling element according to claim 1, wherein a lead terminal of the heat dissipating lead frame that has been led outside is used as the lead terminal of the power element.

12. A method for producing an optical coupling element, comprising:
a step of, in a state in which a light emitting element that has been mounted to a light emitting lead frame, and a light receiving element that has been mounted to a light receiving lead frame and a power element that has been mounted to a power lead frame, have been disposed facing each other, entirely molding the light emitting element, the light receiving element and the power element with a primary molding resin,
a step of forming a lead terminal by cutting the power lead frame, which is led out from the first molding resin, and to which the power element has been mounted, and
a step of stacking together the lead terminal and the heat dissipating lead frame in which a heat sink is formed, and in this state, molding the primary molding resin and the heat sink entirely with a secondary molding resin.

13. The method for producing an optical coupling element according to claim 12, further comprising a step in which a connection is made in a stacked portion where the lead terminal and the heat dissipating lead frame in which the heat sink is formed are stacked together.

14. The method for producing an optical coupling element according to claim 13, wherein the connection step is any of making a connection by soldering, making a connection by welding, or making a connection by gluing.

15. An electronic device in which the optical coupling element according to claim 1 has been mounted.

16. The optical coupling element according to claim 2, wherein a lead terminal of the heat dissipating lead frame that has been led outside is used as the lead terminal of the power element.

17. The optical coupling element according to claim 3, wherein a lead terminal of the heat dissipating lead frame that has been led outside is used as the lead terminal of the power element.

18. The optical coupling element according to claim 4, wherein a lead terminal of the heat dissipating lead frame that has been led outside is used as the lead terminal of the power element.

19. The optical coupling element according to claim 5, wherein a lead terminal of the heat dissipating lead frame that has been led outside is used as the lead terminal of the power element.

20. The optical coupling element according to claim 6, wherein a lead terminal of the heat dissipating lead frame that has been led outside is used as the lead terminal of the power element.
